(19) United States
(12) Patent Application Publication
(10) Pub. No.: US 2012/0111396 A1
(43) Pub. Date: May 10, 2012

(54) Photovoltaic Devices and Associated Methods

(75) Inventors: Stephen D. Saylor, South Hamilton, MA (US); Jason Sickler, Arlington, MA (US); James Carey, Waltham, MA (US); Christopher Vineis, Watertown, MA (US); Xia Li, Beverly, MA (US)

(73) Assignee: SiOnyx, Inc., Beverly, MA (US)

(21) Appl. No.: 13/101,072

(22) Filed: May 4, 2011

Related U.S. Application Data
(60) Provisional application No. 61/331,154, filed on May 4, 2010.
(60) Provisional application No. 61/380,110, filed on Sep. 3, 2010.

(51) Int. Cl. H01L 31/0352; H01L 31/18

(52) U.S. Cl. 136/255; 438/4; 438/71; 257/E31.13

(57) ABSTRACT

A method for making a semiconductor device includes providing a semiconductor material and doping at least a portion of the semiconductor material to form at least one doped region. A portion of the semiconductor material is removed with a pulsed laser from at least one first region to form at least one adjacent second region.

### PRIORITY DATA

This application claims the benefit of U.S. Provisional Patent Application Ser. No. 61/331,154, filed on May 4, 2010, and U.S. Provisional Patent Application Ser. No. 61/380,110, filed on Sep. 3, 2010, both of which are incorporated herein by reference.

### BACKGROUND

The interaction of light with semiconductor devices is utilized in a variety of innovations and technology. For example, as greenhouse emissions damage the environment, more people are turning to alternative energy solutions for power. One alternative energy approach utilizes photovoltaic solar cells to absorb and convert light rays from the sun into usable energy. Photovoltaic solar cells have been used for a number of years with increasing developments and improvements to the technology.

A typical photovoltaic device can include a photovoltaic cell that can be formed from a silicon material. Silicon is known to absorb a majority of incident visible light having wavelengths in the range of about 300 nm to 900 nm. This, combined with quantum efficiency in the visible and near-infrared spectrum, make silicon a good choice for light absorption. However, the electrical band gap of silicon (i.e. 1.12 eV or alternatively approximately 1100 nm) is such that many wavelengths of light are substantially transparent to silicon, and thus pass through the material without being absorbed.

Various methods exist for manufacturing photovoltaic devices. A selective emitter is often created by doping a material to produce a heavily doped region beneath electrically conductive contacts. A basic photovoltaic device often includes an emitter (or a selective emitter) and a photovoltaic diode. The photovoltaic diode captures certain incident photons and converts at least some of them into electricity. Such devices can operate at low temperatures and without moving parts.

### SUMMARY

The present disclosure provides devices and methods which address inefficiencies in photovoltaic devices and the manufacture of photovoltaic devices. In accordance with examples of the technology, a semiconductor device such as a selective emitter can be substantially simultaneously created on a surface of a photovoltaic device while forming a surface texture in an active region.

A method for making a semiconductor device in accordance with an example of the present technology includes providing a semiconductor material and doping at least a portion of the semiconductor material to form at least one doped region. The method further includes removing a portion of the semiconductor material with a pulsed laser from at least one first region within the at least one doped region to form at least one adjacent second region.

A method for making a semiconductor device in accordance with another example of the present technology includes providing a semiconductor material, doping at least one first region of the semiconductor material with a first dopant, and doping at least one second region of the semiconductor material with a second dopant. The at least one second region is adjacent to the at least one first region. The method further includes texturing the at least a portion of the at least one first region using a pulsed laser to form at least one textured region.

A photovoltaic device, in accordance with an example of the present technology, includes a semiconductor material, and at least one doped first region on the semiconductor material. The at least one doped first region includes an at least one first laser textured region including surface features. The photovoltaic device further includes at least one doped second region on the semiconductor material adjacent to the at least one doped first region.

### BRIEF DESCRIPTION OF THE DRAWINGS

For a fuller understanding of the nature and advantage of the present invention, reference is being made to the following detailed description of preferred embodiments and in connection with the accompanying drawings, in which:

FIGS. 1a-1c are cross-sectional side views of a photovoltaic device at different stages of manufacture in accordance with one aspect of the present disclosure;

FIG. 2 is a flow diagram of a method for manufacturing a photovoltaic device in accordance with another aspect of the present disclosure;

FIG. 3 is illustrates cross-sectional side views of a photovoltaic device at different stages of manufacture as shown in FIG. 2;

FIG. 4 is a cross-sectional side view of a photovoltaic device having first and second textured regions in accordance with another aspect of the present disclosure;

FIGS. 5a-5c are top views of photovoltaic devices having arrays of emitters and active regions in accordance with another aspect of the present disclosure;

FIG. 6 is a cross-sectional side view of a photovoltaic device in accordance with another aspect of the present disclosure; and

FIGS. 7-8 are flow diagrams of methods for making semiconductor devices in accordance with further aspects of the present disclosure.

### DETAILED DESCRIPTION

Before the present disclosure is described herein, it is to be understood that this disclosure is not limited to the particular structures, process steps, or materials disclosed herein, but is extended to equivalents thereof as would be recognized by those ordinarily skilled in the relevant arts. It should also be understood that terminology employed herein is used for the purpose of describing particular embodiments only and is not intended to be limiting.

### DEFINITIONS

The following terminology will be used in accordance with the definitions set forth below.

It should be noted that, as used in this specification and the appended claims, the singular forms “a,” and, “the” include plural referents unless the context clearly dictates otherwise. Thus, for example, reference to “a dopant” includes one or more of such dopants and reference to “the layer” includes reference to one or more of such layers.

As used herein, the terms “light” and “electromagnetic radiation” can be used interchangeably and can refer to light or electromagnetic radiation in the ultraviolet, visible, near infrared, and infrared spectra. The terms can further more broadly include electromagnetic radiation such as radio waves, microwaves, x-rays, and gamma rays. Thus, the term “light” is not limited to electromagnetic radiation in the visible spectrum.

As used herein, the terms “surface modifying” and “surface modification” refer to the altering of a surface of a semiconductor material using a variety of surface modification techniques. Non-limiting examples of such techniques include plasma etching, reactive ion etching, porous silicon etching, lasing, chemical etching (e.g. anisotropic etching, isotropic etching), nanoimprinting, material deposition, selective epitaxial growth, and the like, including combinations thereof. In one specific aspect, surface modification can include processes using primarily laser radiation or laser radiation in combination with a dopant, whereby the laser radiation facilitates the incorporation of the dopant into a surface of the semiconductor material. Accordingly, in one aspect surface modification includes doping of a substrate such as a semiconductor material. In one aspect, a semiconductor surface can be modified to become an absorption enhanced surface. Also, a surface modified surface can include, for example, a textured surface. As used herein, the term “textured surface” can refer to a surface having a topology with nanometer to micrometer-sized surface variations formed by irradiation with laser pulses or other texturing methods as are described herein. While the characteristics of such a surface can be variable depending on the materials and techniques employed, in one aspect such a surface can be several hundred nanometers thick and made up of nanocrystallites (e.g. from about 10 to about 50 nanometers) and nanopores. In another aspect, such a surface can include micro-sized structures (e.g. about 2 μm to about 60 μm). In yet another aspect, the surface can include nano-sized and/or micro-sized structures from about 5 nm and about 500 μm.

As used herein, the term “fluence” refers to the amount of energy from a single pulse of laser radiation that passes through a unit area. In other words, “fluence” can be described as the energy density of one laser pulse.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result. For example, a composition that is “substantially free of” particles would either completely lack particles, or so nearly completely lack particles that the effect would be the same as if it completely lacked particles. In other words, a composition that is “substantially free of” an ingredient or element may still actually contain such item as long as there is no measurable effect thereof.

As used herein, the term “about” is used to provide flexibility to a numerical range endpoint by providing that a given value may be “a little above” or “a little below” the endpoint.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 to about 5” should be interpreted to include not only the explicitly recited values of about 1 to about 5, but also include individual values and sub-ranges within the indicated range. Thus, included in this numerical range are individual values such as 2, 3, and 4 and sub-ranges such as from 1-3, from 2-4, and from 3-5, etc., as well as 1, 2, 3, 4, and 5, individually.

This same principle applies to ranges reciting only one numerical value as a minimum or a maximum. Furthermore, such an interpretation should apply regardless of the breadth of the range or the characteristics being described.

The Disclosure

The following disclosure relates to photovoltaic semiconductor devices. More specifically, the present disclosure relates to devices having at least one textured region of a semiconductor material with emitters formed on the semiconductor material and methods of making the same.

A method for making a semiconductor device in accordance with an example of the present technology includes providing a semiconductor material and doping at least a portion of the semiconductor material to form at least one doped region. The method further includes removing a portion of the semiconductor material with a pulsed laser from at least one first region within a portion of the at least one doped region to form at least one adjacent second region.

The at least one first region can be a light diffusing region or a textured region, such as a laser-textured region. Throughout this disclosure, the light diffusing region is referred to as a textured region for simplicity and ease of discussion. However, other forms of light diffusing or light scattering regions are also contemplated. For example, the textured surface can also be created by various methods, such as anisotropic etch, isotropic etch, nanoimprint methods, and the like.

The textured region may be formed by a laser process as disclosed, for example, in U.S. Pat. Nos. 7,057,256, 7,354,792, and 7,442,629, which are incorporated by reference herein in their entirety. The textured region may comprise a semiconductor material, for example silicon, which is irradiated by a short pulse laser or other texturing technique to create modified surface morphology. The textured semiconductor is made to have advantageous light-absorbing properties. The textured surface can also exhibit anti-reflective properties, which assist in the absorption of light.

The wavelength of the irradiating laser pulse for making the textured region, its fluence, and pulse duration can affect the morphology of the modified surface. In some embodiments, the laser fluence may be between about 0.5 kJ/m² and 12 kJ/m², but can vary depending on the substrate composition. The choice of the fluence of laser pulses irradiating a silicon wafer to generate a micro structured or nanostructured layer therein can also affect the gettering performance (capacity and/or specificity) of a substrate. In one aspect, the laser pulse fluence is greater than about 3 kJ/m². In another aspect, the fluence is in a range of from about 3 kJ/m² to about 10 kJ/m². In yet another aspect, the fluence is in a range of from about 3 kJ/m² to about 8 kJ/m².

Additionally, the laser pulse duration can affect the morphology and absorption properties of the modified semiconductor surface. Irradiation of a substrate can be with femtosecond laser pulses or picosecond or nanosecond pulses. Other factors that can affect surface morphology include laser polarization and laser propagation direction relative to the irradiated semiconductor surface.

As has been described, a laser, or radiation from a laser, can be used to create textured surfaces on a semiconductor material. The fluence of the laser is related to the size of the features in the textured region(s). On average, a lower laser fluence results in smaller features, while a higher laser fluence results in larger features. The second region in this example includes small random cone-like features having a height in the range of about 0.005 nm to about 10 μm, or from about 0.01 nm to about 5 μm from base or valley to apex or tip. In one aspect, the height of a feature can be measured as a lowest point on a side of the feature to a highest point on the feature. In another aspect, the height of the feature can be measured as a depth of the textured feature in the semiconductor material from an original upper plane of the semiconductor material prior to texturing. A fluence of the laser at less than about 6 kJ/m² can result in such smaller features. In the first or active region, the laser fluence can be increased to create larger surface features having a size of from about 50 nm to 50 μm, or from about 200 nm to about 10 μm. These larger surface features can be formed by applying a laser having a fluence of from about 6 kJ/m² to about 8 kJ/m², where other lasing parameters are held constant as compared with the lasing parameters used in formation of the smaller surface features. However, with variation in the lasing parameters, such as a process gas composition, for example, the fluence can range from approximately 0.1 kJ/m² to about 8 kJ/m² and result in the larger feature sizes. The larger features can be formed to optimize light absorption. Various implementations of photovoltaic devices having textured regions are contemplated, such as devices including one or two textured regions or even additional regions (e.g. a third and forth textured region). The additional regions may also vary in texture feature sizes and shapes, as well as doping levels, as compared with the first and/or second regions.

Controlling the laser fluence can be accomplished by varying the laser spot size and/or total laser pulse energy. In addition to laser fluence modulation, other techniques can be employed to form the different textured regions such as varying the number of laser pulses or shots that are deployed on a given area. For example, the number of laser pulses irradiating a target region can be in a range of from about 1 to about 2000. In one aspect, the number of laser pulses irradiating a target region can be from about 2 to about 1000. Further, the repetition rate or frequency of the pulses can be selected to be in a range of from about 10 Hz to about 10 μHz, or in a range of from about 1 kHz to about 1 MHz, or in a range from about 10 Hz to about 1 kHz.

Further, the environment in which the semiconductor material is laser processed can have an effect on the size of the features. For example, lasing the semiconductor material in a liquid can create smaller features than lasing in gas. The process of lasing the semiconductor material in a liquid is described in U.S. patent application Ser. No. 12/038,209, filed on Feb. 27, 2008, which is incorporated herein by reference in its entirety.

Because the absorption properties of silicon change with wavelength, altering the laser wavelength in order to change how the optical energy is deposited in the silicon substrate in this manner can also result in different sizes in surface features. The laser wavelengths can be in the range of from about 10 nm to 8 μm, or from 200 nm to about 3000 nm, or from 200 nm to about 1,200 nm. Some other variables which can also affect the size of the textured features include a laser pulse number (i.e., the number of laser pulses to which the semiconductor material is exposed during the laser processing timescale), a laser pulse duration, and a number of lasers lasing the first or second target region.

In some embodiments, a textured region can be doped with a dopant, either separately from or during the texturing process. For example, in the case of laser texturing, the laser radiation can be directed through a dopant material to incorporate the dopant into the texture region. For example, in one aspect silicon can be laser textured in the presence of SF₆ in order to incorporate S (sulfur) into the textured region.

A more detailed description of an exemplary apparatus for detecting electromagnetic radiation or light in the electromagnetic spectrum will now be provided.

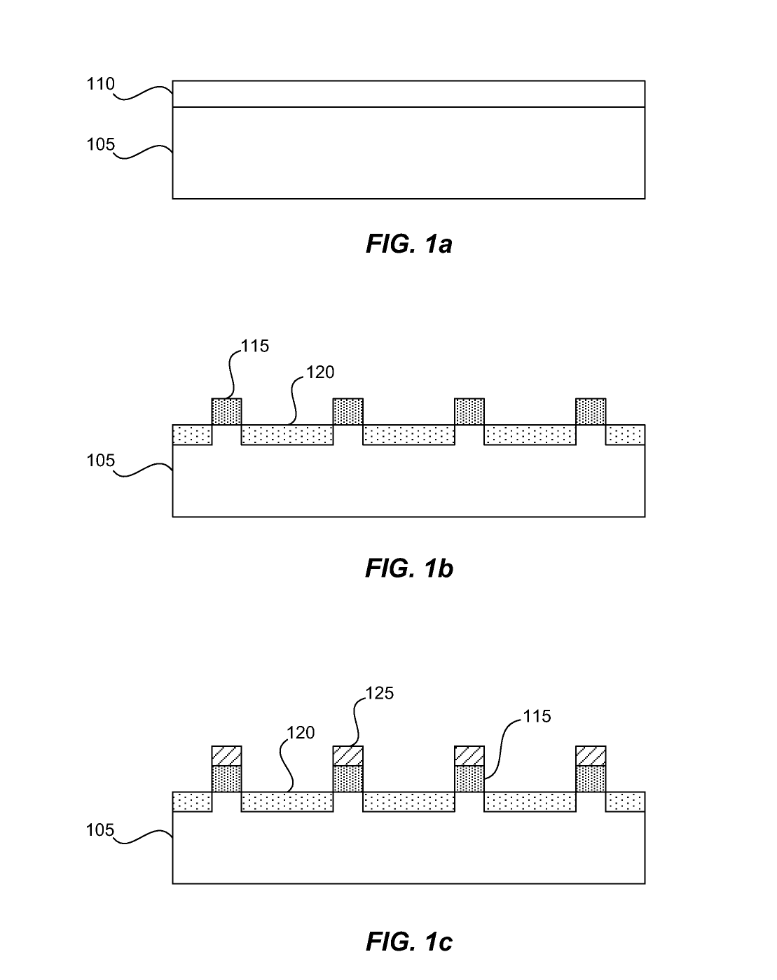

Reference will now be made to FIGS. 1a-1c. FIGS. 1a-1c illustrate progressive steps in making a photovoltaic device which can have an architecture that results in good contact resistance (low) at the point of electrically conductive contacts and increased resistivity in regions outside of the contacts (active region). Generally, a doping process can create a highly doped region appropriate for contact metallization. A laser process can ablate and remove highly doped material from the surface, leaving behind both a lower-doped surface that is suitable for a non-metalized, active region, along with a texture for anti-reflective and long wavelength quantum efficiency enhancement.

A silicon photovoltaic cell can include a selective emitter architecture for enhanced performance. The selective emitter architecture has increased doping levels located directly under the electrically conductive contacts and has reduced or opposite polarity dopants in the remaining regions of the device (i.e., the active regions). An optimized device may have high dopant levels for good electrical contact resistivity and a high open-circuit voltage. Auger recombination is more persistent at the higher dopant levels. Auger recombination is an effect in semiconductors in which an electron and electron-hole (electron-hole pair) can recombine, giving up energy to an electron in the conduction band and increasing the energy of the electron in the conduction band. In a selective emitter architecture, it is desirable to reduce Auger recombination in the active regions and improve quantum efficiency, especially across wavelengths in the blue portion of the electromagnetic spectrum. There exists a difficulty in striking a balance or trade-off between dopant levels in the active regions and dopant levels beneath the contacts. The use of a selective emitter architecture provides for high doping levels under the contacts, enabling a good contact resistivity and open-circuit voltage, while also providing for low doping in the active region to suppress Auger recombination and provide improved quantum efficiency.

FIG. 1a shows a cross section of a semiconductor material 105, such as a silicon substrate, having a dopant 110 disposed on or driven into at least one surface of the semiconductor material. For example, the dopant may include a POCl₃ material. The dopant can be driven into the semiconductor material by any of a variety of doping methods described herein to form a doped region of the semiconductor material. FIG. 1b illustrates the device after irradiation by a laser to form first 120 and second 115 regions on the semiconductor material. The dopant is at least partially removed from the first regions of the semiconductor material processed by the laser. As a result, selective emitter regions, or regions with a higher dopant concentration (i.e., the amount of dopant per volume of the semiconductor material), are formed. This will lead to lower sheet resistance in the first regions as compared to that in the second regions. Also, the laser irradiation can create a textured region on a surface of the silicon semiconductor device. FIG. 1c shows an electrically conductive material 125 disposed on the selective emitter regions where the emitter or higher dopant regions are located.

Selective emitters are typically located underneath front side contacts of a solar cell. The emitter regions are highly doped with a dopant species such that the contact or sheet resistance is reduced in order to induce or promote electrical current flow.

The dopant used in the device can be determined by the bulk semiconductor substrate. Various known doping processes are contemplated for doping or infusing a charge donating constituent into the substrate. In one embodiment, for example, the dopant can be grown within the substrate. In another embodiment the dopant can be infused in to the semiconductor material to a certain depth via the top surface by ion implantation or laser doping process. One such ion implantation method is described in U.S. patent application Ser. No. 12/553,861, filed on Sep. 3, 2009, which is incorporated herein by reference in its entirety. It can be desirable to have higher dopant concentrations under the contact region than at the exposed surface between the contacts in order to improve the current flow while reducing the amount of electron-hole recombination that takes place in the device.

A variety of semiconductor materials are contemplated for use with the devices and methods according to aspects of the present disclosure. Non-limiting examples of such semiconductor materials can include group IV materials, compounds and alloys comprised of materials from groups II and VI, compounds and alloys comprised of materials from groups III and V, and combinations thereof. More specifically, exemplary group IV materials can include silicon, carbon (e.g. diamond), germanium, and combinations thereof. Various exemplary combinations of group IV materials can include silicon carbide (SiC) and silicon germanium (SiGe). In one specific aspect, the semiconductor material can be or include silicon. Exemplary silicon materials can include amorphous silicon (a-Si), microcrystalline silicon, multicrystalline silicon, and monocrystalline silicon, as well as other crystal types. In another aspect, the semiconductor material can include at least one of silicon, carbon, germanium, aluminum nitride, gallium nitride, indium gallium arsenide, aluminum gallium arsenide, and combinations thereof.

Exemplary combinations of group II-VI materials can include cadmium selenide (CdSe), cadmium sulfide (CdS), cadmium telluride (CdTe), zinc oxide (ZnO), zinc selenide (ZnSe), zinc sulfide (ZnS), zinc telluride (ZnTe), cadmium zinc telluride (CdZnTe, CZT), mercury cadmium telluride (HgCdTe), mercury zinc telluride (HgZnTe), mercury zinc selenide (HgZnSe), and combinations thereof.

Exemplary combinations of group III-V materials can include aluminum antimonide (AlSb), aluminum arsenide (AlAs), aluminum nitride (AlN), aluminum phosphide (AlP), boron nitride (BN), boron phosphide (BP), boron arsenide (BAs), gallium antimonide (GaSb), gallium arsenide (GaAs), gallium nitride (GaN), gallium phosphide (GaP), indium antimonide (InSb), indium arsenide (InAs), indium nitride (InN), indium phosphide (InP), aluminum gallium arsenide (AlGaAs, AlxGal-xAs), indium gallium arsenide (InGaAs, InxGal-xAs), indium gallium phosphide (InGaP), aluminum indium arsenide (AlInAs), aluminum indium antimonide (AlInSb), gallium arsenide nitride (GaAsN), gallium arsenide phosphide (GaAsP), aluminum gallium nitride (AlGaN), aluminum gallium phosphide (AlGaP), indium gallium nitride (InGaN), indium arsenide antimonide (InAsSb), indium gallium antimonide (InGaSb), aluminum gallium indium phosphide (AlGaInP), aluminum gallium arsenide phosphide (AlGaAsP), indium gallium arsenide phosphide (InGaAsP), aluminum indium arsenide phosphide (AlInAsP), aluminum gallium arsenide nitride (AlGaAsN), indium gallium arsenide nitride (InGaAsN), indium aluminum arsenide nitride (InAlAsN), gallium arsenide antimonide nitride (GaAsSbN), gallium indium nitride arsenide antimonide (GaInNAsSb), gallium indium arsenide antimonide phosphide (GaInAsSbP), and combinations thereof.

The semiconductor substrate can be of any thickness that allows electromagnetic radiation detection and conversion functionality, and thus any such thickness of semiconductor material is considered to be within the present scope. In some aspects the textured region increases the efficiency of the device such that the semiconductor substrate can be thinner than has previously been possible. Decreasing the thickness of the semiconductor substrate reduces the amount of semiconductor material required to make such a device. In one aspect, for example, the semiconductor substrate has a thickness of from about 500 nm to about 50 μm. In another aspect, the semiconductor substrate has a thickness of less than or equal to about 100 μm. In yet another aspect, the semiconductor substrate has a thickness of from about 1 μm to about 10 μm. In a further aspect, the semiconductor substrate can have a thickness of from about 5 μm to about 50 μm. In yet a further aspect, the semiconductor substrate can have a thickness of from about 5 μm to about 10 μm.

Additionally, various types of semiconductor materials are contemplated, and any such material that can be incorporated into an electromagnetic radiation detection device is considered to be within the present scope. In one aspect, for example, the semiconductor material is monocrystalline. In another aspect, the semiconductor material is multicrystalline. In yet another aspect, the semiconductor material is microcrystalline. It is also contemplated that the semiconductor material can be amorphous. Specific nonlimiting examples include amorphous silicon or amorphous selenium.

The semiconductor materials of the present disclosure can also be made using a variety of manufacturing processes. In some cases the manufacturing procedures can affect the efficiency of the device, and may be taken into account in achieving a desired result. Exemplary manufacturing processes can include Czochralski (Cz) processes, magnetic Czochralski (mCz) processes, Float Zone (FZ) processes, epitaxial growth or deposition processes, and the like. It is contemplated that the semiconductor materials used in the present invention can be a combination of monocrystalline material with epitaxially grown layers formed thereon.

The textured region(s) can function to scatter electromagnetic radiation, to redirect electromagnetic radiation, and to absorb electromagnetic radiation, thus increasing the quantum efficiency of the device. In one aspect, electromagnetic radiation passing through the semiconductor substrate can contact the textured region. The textured region can include surface features to increase the effective absorption length of the photovoltaic solar cell. Such surface features can be micro-sized and/or nano-sized, and can be any shape or configurations. Non-limiting examples of such shapes and configurations include cones, pillars, pyramids, micolenses, quantum dots, inverted features, gratings, protrusions, and the like, including combinations thereof.

Textured regions according to aspects of the present disclosure can allow a photovoltaic device to experience multiple passes of incident electromagnetic radiation within the device, particularly at longer wavelengths (i.e. infrared). Such internal reflection increases the effective absorption length to be greater than the physical thickness of the semiconductor substrate. This increase in absorption length increases the quantum efficiency of the device. As such, in one aspect a secondary textured region can be created on the semiconductor material on a surface that is opposite the textured region of the absorptive region (i.e., the backside of the semiconductor material). This can allow electromagnetic radiation passing through the semiconductor material to be redirected back toward the absorptive region.

In addition to surface features, the textured region (and/or the secondary textured region) can have a surface morphology that is designed to focus or otherwise direct electromagnetic radiation. For example, in one aspect the textured region has a surface morphology operable to preferentially direct electromagnetic radiation into the semiconductor substrate (i.e., to trap or capture light). Non-limiting examples of various surface morphologies include sloping, pyramidal, inverted pyramidal, spherical, square, rectangular, parabolic, asymmetric, symmetric, and the like, including combinations thereof.

Laser processing to create textured regions can occur with or without a dopant material. In those aspects whereby a dopant is used, the laser can be directed through a dopant carrier and onto the substrate surface. In this way, dopant from the dopant carrier is introduced into the target region of the substrate material. Such a region incorporated into a substrate material can have various benefits in accordance with aspects of the present disclosure. For example, the target region typically has a textured surface that increases the surface area of the laser treated region and increases the probability of radiation absorption via the mechanisms described herein.

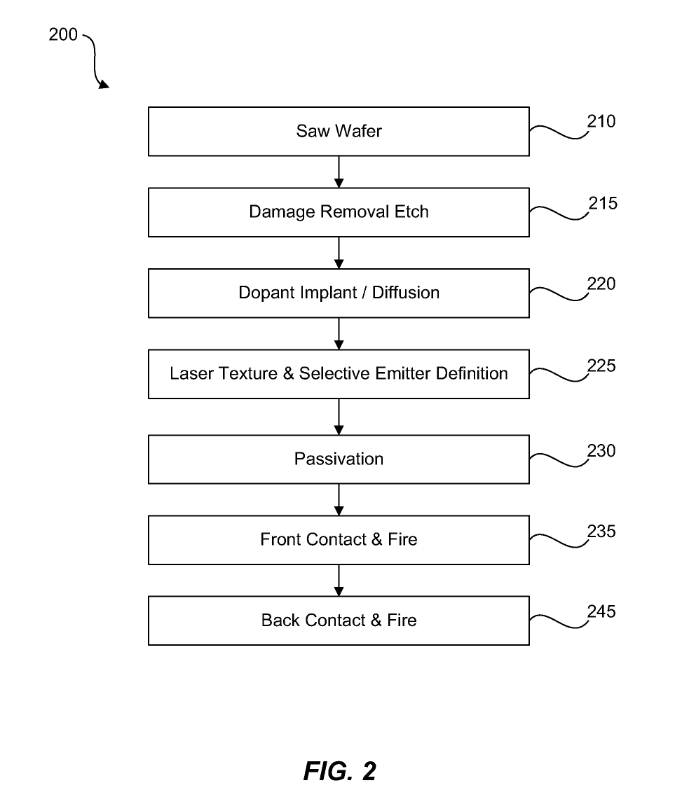

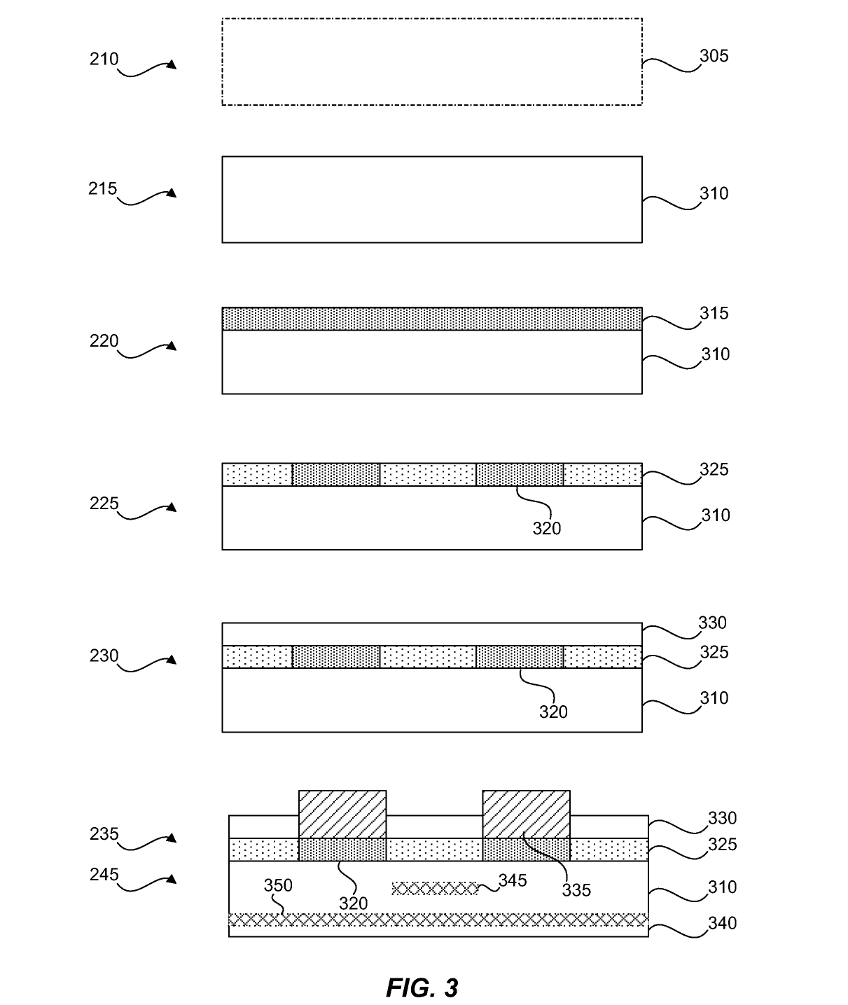

Referring to FIGS. 2-3 a process flow 200 of making a photovoltaic device is shown in FIG. 2, while a cross-section of the photovoltaic device at each step of the process is shown in FIG. 3. The steps of the process can include providing 210 a saw-cut semiconductor wafer 305, which may have saw damage from being separated from a semiconductor ingot. The saw damage can be removed with a damage removal etching (DRE) process 215, resulting in a substantially flat or smooth semiconductor wafer surface 310.

Conventional crystalline solar cell processing involves a damage removal etch (DRE) step and a chemical etch-based texturing step. The chemistries for these steps are generally different. By using a laser-based texturing step a DRE etch chemistry can be optimized, thereby providing a potentially higher quality DRE as well as a potentially shorter processing time. The higher quality DRE may be realized by reducing the damage created by the multiple chemical processing steps through replacement of at least some of these multiple chemical processing steps with the laser processing step. A smooth wafer surface can yield better crystalline defect gettering effects during a phosphorous based emitter diffusion process. This in turn improves wafer bulk lifetime and efficiency.

Continuing with reference to the process flow 200 and device cross-sections shown in FIGS. 2-3, a dopant 315 can be diffused on or implanted 220 into the semiconductor material 310 to achieve a desired sheet resistivity in emitter regions. The dopant may be, for example, a charge donating constituent. Some dopants can be added to the silicon-based material in growth, giving the silicon wafer a nearly uniform doping profile. Additional dopants may be introduced into the material to further enhance a particular polarity of the substrate. The additional dopant can be applied to the substrate by any of various known methods such as ion doping, diffusion doping, plasma deposition, sputtering, and so forth. In some embodiments, variations of n(−−), n(−), n(+), n(++), p(−−), p(−), p(+), or p(++) type semiconductor layers may be used for any doped regions of the device. The “p” is indicative of positive polarity and “n” is indicative of negative polarity.

The dopant material can include, for example, a phosphorus material (i.e. POCl₃). A variety of dopant materials are contemplated for both the formation of the multiple doped regions and incorporation by a texturing technique, and any such dopant that can be used in such processes to surface modify a material is considered to be within the present scope. It should be noted that the particular dopant utilized can vary depending on the material being doped, as well as the intended use of the resulting material.

In one aspect, non-limiting examples of dopant materials can include S, F, B, P, N, As, Se, Te, Ge, C, Cl, Ar, Al, O, Ga, In, Sb, or any other group III, IV, V, VI and/or VII atoms, and combinations thereof. It should be noted that the scope of dopant materials should include, not only the dopant materials themselves, but also materials in forms that deliver such dopants (i.e. dopant carriers). For example, S dopant materials includes not only S, but also any material capable being used to dope S into the target region, such as, for example, H₂S, SF₆, SO₂, and the like, including combinations thereof. In one specific aspect, the dopant can be S. Sulfur can be present at an ion dosage level of between about 5×10¹⁴ and about 1×10²¹ ions/cm². Non-limiting examples of fluorine-containing compounds can include ClF₃, PF₅, F₂ SF₆, BF₃, GeF₄, WF₆, SiF₄, HF, CF₄, CHF₃, CH₂F₂, CH₃F, C₂F₆, C₂HF₅, C₃F₈, C₄F₈, NF₃, and the like, including combinations thereof. Non-limiting examples of boron-containing compounds can include B(CH₃)₃, BF₃, BCl₃, BN, C₂B₁₀H₁₂, borosilica, B₂H₆, and the like, including combinations thereof. Non-limiting examples of phosphorous-containing compounds can include PF₅, PH₃, and the like, including combinations thereof. Non-limiting examples of chlorine-containing compounds can include Cl₂, SiH₂Cl₂, HCl, SiCl₄, and the like, including combinations thereof. Dopants can also include arsenic-containing compounds such as AsH₃ and the like, as well as antimony-containing compounds. Additionally, dopant materials can include mixtures or combinations across dopant groups, i.e. a sulfur-containing compound mixed with a chlorine-containing compound. In one aspect, the dopant material can have a density that is greater than air. In one specific aspect, the dopant material can include Se, H₂S, SF₆, or mixtures thereof. In yet another specific aspect, the dopant can be SF₆ and can have a predetermined concentration range of about 5.0×10⁻⁸ mol/cm³ to about 5.0×10⁻⁴ mol/cm³. As one non-limiting example, SF₆ gas is a good carrier for the incorporation of sulfur into the semiconductor material via a laser process without significant adverse effects on the material. Additionally, it is noted that dopants can also be liquid solutions of n-type or p-type dopant materials dissolved in a solution such as water, alcohol, or an acid or basic solution. Dopants can also be solid materials applied as a powder or as a suspension dried onto the wafer.

A region in which the dopant is disposed is a doped region 315 of the semiconductor material 310. The dopant can be introduced 220 into the device material to a desired depth. For example, the dopant may be introduced to a depth of less than about 1 micron. A dopant concentration may be higher near the surface of the material and may be reduced at a depth from the surface. In another aspect, the dopant can be uniform throughout the doped region. In one example, a boron or phosphorus (e.g. POCl₃) dopant can be doped into the substrate to a depth of less than half of the thickness of the semiconductor substrate. In an example where a dopant is applied with laser processing, more than one laser processing step can be used to enable uniform doping that is conformal to the texture surface while still allowing the selective laser removal of a portion of the doped region to form the selective emitter(s).

The semiconductor device can be laser processed 225 to form selective emitting regions 320 in second regions and active regions 325 in first regions. An optional damage removal etch (DRE) step can subsequently be used to remove a portion of any damaged caused by the laser. The laser processing can include ablation and removal of part of the dopant region using a laser having laser pulses in a range of, for example, from about 10 femtoseconds to 900 picoseconds, or from about 10 femtoseconds to 500 picoseconds, or from about 10 femtoseconds to 100 picoseconds, or from about 10 femtoseconds to 50 picoseconds, or from about 10 femtoseconds to about 900 femtoseconds. The laser processing can be engineered around the emitter doping process so that a final emitter junction depth and doping concentration is adjustable. The adjustability provides freedom between the case of low recombination and low contact resistance for different electrically conductive material contact processes. The textured or first region(s) can have textured features which can have a height of from about 1 nm to about 5 μm. In a more detailed aspect, the textured features can have a height of from about 1 nm to about 3 μm or from about 1 nm to about 1 μm. In one example, an average removal depth to which the portion of the semiconductor material is removed with the pulsed laser is from approximately 1 nm to 1 μm, or 1 nm to 3 μm, or 1 nm to 5 μm.

In one aspect, the second regions 320 can be un-lased regions and the first regions 325 can be textured regions. In one aspect, a sheet resistance in the first, active, or textured region can be in a range of from about 80 to about 200Ω/□. In another aspect, the sheet resistance in the first region is from about 100 to about 150Ω/□. The first region can have a higher sheet resistance than the second or emitter region. For example, the sheet resistance of the first region can be at least one and a half times greater, or more preferably at least two times greater, than the sheet resistance of the second region. Before texturing and/or emitter definition process, the first and second regions may have a substantially similar sheet resistance. The sheet resistance of the first region can be increased by removing at least a portion of the dopant from the semiconductor material. Not removing dopant from the second region, or at least removing dopant from the second region in a smaller amount, can result in a lower sheet resistance for the emitters. For example, the sheet resistance in the second region can be between approximately 30 and 50Ω/□, or less than approximately 60Ω/□, or more preferably less than approximately 40Ω/□. For example, the sheet resistance can be as low as approximately 0.038Ω/□ for a multi-crystalline photovoltaic solar cell, or as low as approximately 0.001Ω/□.

Many photovoltaic devices are produced from amorphous, micro-crystalline, and multi-crystalline silicon, having a lattice network that can be disordered. The disordered material can include “dangling bonds” atoms. Dangling bonds are defects in the material that cause electron hole recombination, thus reducing the electrical efficiency of the device. Surface passivation can be helpful to minimize the recombination of the charge carriers in the material. Hydrogen can be used to bond with the dangling bonds thereby limiting the amount of recombination centers found in the device. Many photovoltaic devices are processed with plasma enhanced chemical vapor deposition (PECVD) utilizing ammonia (NH₃) and silane (SiH₄) to quench the dangling bonds with hydrogen molecules and form a silicon nitride (SiN) passivation layer that can also act as an anti-reflecting coating.

A passivation layer 330, such as nitride for example, can be disposed 230 over at least one surface of the device. The passivation can be used on the surface that is lased. Non-limiting examples of passivation materials can include nitrides, oxides, amorphous silicon, amorphous silicon carbide, and the like, including combinations thereof. Alternatively, passivation on the textured active region or elsewhere may be omitted.

The passivation region 330 can be made from a variety of materials, and such materials can vary depending on the device design and desired characteristics. Non-limiting examples of such materials can include oxides, nitrides, oxynitrides, and the like, including combinations thereof. In one specific aspect, the passivation region includes an oxide. Additionally, the passivation region can be of various thicknesses. In one aspect, for example, the passivation region has a thickness of from about 100 nm to about 1 μm. In another aspect, the passivation region has a thickness of from about 5 nm to about 100 nm. In yet another aspect, the passivation region has a thickness of from about 20 nm to about 50 nm. In one embodiment, the passivation region can be an anti-reflecting region.

An electrically conductive material 335 can disposed 235 as a front contact on a front side of the device and/or a back side electrically conductive material 340 can be disposed 245 as a back contact on a back side of the device, and the contact material(s) can be cured or fired. Aluminum doping on the backside of the device can lead to unwanted higher recombination. Therefore, in one embodiment, a material such as a boron doped backside is used to form a back surface active region. An electrically conductive material, such as silver or aluminum, can be used to form contacts over the selective emitters. This embodiment enables the implementation of a dielectric layer disposed on the back surface (thereby forming a passivation layer), which further reduces back surface recombination in addition to back surface field effects. Using silver based contacts, such as in the form of a silver paste for example, can enable a simplified manufacturing process which allows for side screen printing and firing, which can ultimately lower manufacturing costs. In some aspects, the contacts may be made from a metal such as silver or aluminum, while in other aspects, the contacts may be conductive contacts formed from Indium Tin Oxide (ITO), a Transparent Conductive Oxide (TCO), a conductive polymer, or any other suitable conductive material. The contacts can be deposited by a screen printing process or a variety of other known metal deposition processes.

Alignment of the electrically conductive contacts to the selective emitter regions can be enabled by optical inspection because the selective emitter regions are highly reflective while the lased active region regions are non-reflective. In one aspect, a process of forming a photovoltaic device, or more specifically, a selective emitter, includes self-aligned metallization. This process flow begins with providing a saw-cut wafer, followed by a damage removal etching process. A dopant is applied to the wafer in blanket fashion to form an emitter. The wafer can be metallized, such as in a desired pattern. Subsequently, the front or metallized surface of the wafer is lased. Lasing in the non-metallized (active region) areas of the emitter reduces the doping level and creates surface textures as described above. Lasing of the metal lines ablates only a small amount of metal and thus has negligible impact on metal line resistance. The emitter area underneath the metal lines is unaffected by the lasing and thus retains a high doping level and low sheet resistance. Thus, the metallization is self-aligned in this process flow. The entire wafer can receive nitride or other passivation, followed by heating of the electrically conductive material. In another aspect, the metal material can be applied to form the contacts and a laser can be applied to non-metallized regions (i.e., active regions) to ablate material from the active regions to produce a textured surface.

While FIGS. 2-3 illustrate dopant application and emitter definition processes as separate or distinct, it is noted that the processes can also be performed substantially simultaneously in a laser processing step. For example, a laser processing step can include laser dopant implantation while substantially simultaneously selectively defining emitter and active regions. Alternately, laser processing can be performed in multiple steps as shown in the figures to first dope and then define regions of the semiconductor material. In another example, the dopant can be applied with ion bombardment, diffusion, and other known processes, followed by the laser processing of the definitions of active and emitter regions.

A single laser or multiple lasers may be used in the laser processing step to facilitate the dopant implantation and emitter definition. Some other variables or parameters that can varied to affect the result of laser processing the active and emitter regions such that the laser processing results in different, useful regions, can include a laser radiation wavelength, a laser pulse number, a laser pulse duration, a laser fluence, and so forth. For example, one or more parameters can have a first setting for processing the emitter regions and a second setting for processing the active regions. In a device including a plurality of emitter regions and a plurality of active regions, a method for continuous laser processing of the regions can include laser processing an emitter region at the first setting, changing the parameter(s) to the second setting, laser processing an active region, changing the parameter(s) back to the first setting, laser processing another emitter region, and so forth.

In one embodiment not shown, the laser contact trenches can be created on the back of the wafers or can be replaced with through-wafer vias to enable either all-backside contacts and/or maximal contact surface area with minimal light shadowing.

In another embodiment not shown, the laser texturing process can be applied to the backside of wafers. This can be advantageous for thinned wafers, such as wafers having a thickness of less than 150 μm. Such a process flow may proceed as follows. The process flow begins with a thin wafer that has saw damage removed. The typical processing for the front side (i.e., the light impinging side) of the wafer is carried out, including doping and the creation of selective emitter regions and active regions. A backside field doping process is carried out to create a back side field (BSF). Laser texturing on the backside can assist in trapping and collecting wavelengths of light that are typically not absorbed in the cell because the absorption coefficient of such wavelengths is long compared to the thickness of the cell.

In one embodiment, the backside of the semiconductor material can be laser processed (including texturing the backside of the semiconductor material) in a blanket configuration to form a backside textured region 350 to assist in trapping and collecting the wavelengths of light that are typically unabsorbed in the cell because the absorption coefficient of such wavelengths is long compared to the thickness of the cell. In another embodiment, an interior region of the semiconductor material can be textured to form an interior textured region 345 by focusing laser radiation at a point within the bulk region. Alternately, the interior texture can be formed by texturing a front or back side surface of a semiconductor material and then sandwiching the textured surface between the semiconductor material and a second semiconductor material.

In another embodiment, the laser process is used to texture the entire front surface of the wafer and to moderately dope regions that will be contacted with metal at a future step. The wafer is then further doped with a process such as dopant diffusion, dopant spray-on, ion implantation, etc. In regions that are both laser doped and doped by the second doping step, the sheet resistivity will be lower (e.g., about 30-50Ω/□). In the regions that were textured and doped by the laser but did not receive the additional doping, the sheet resistivity will be higher (e.g., about 80-100Ω/□) and recombination losses will be lower.

In one aspect, the laser processing can include texturing the first regions by selectively applying a laser radiation to the first regions. For example, a laser processing process can include moving the laser radiation over the semiconductor substrate along a predetermined path. The laser radiation can be impinged on the first regions to texture the first regions and can be caused to not impinge on the second regions as the laser moves over the second regions. The laser can be caused to not impinge on the second regions by a variety of methods which will be recognized by one having skill in the art. Some example methods include: turning the laser off over the second regions and turning the laser on over the first regions; redirecting the laser radiation, such as with a mirror, over the second regions; blocking the laser radiation, such as with a shutter, over the second regions; and so forth.

The predetermined path for the laser processing can follow a path for traveling specifically and primarily over the active regions, for example. As another example, the predetermined path may include a side to side or top to bottom scan of the laser across the semiconductor substrate.

While the foregoing examples are in large part directed toward devices and methods of manufacturing devices where a dopant is substantially uniformly applied to a semiconductor material and then at least partially removed to form emitter and active regions, some example devices and methods can include applying different dopants or applying a same dopant non-uniformly, as will be described in further detail below.

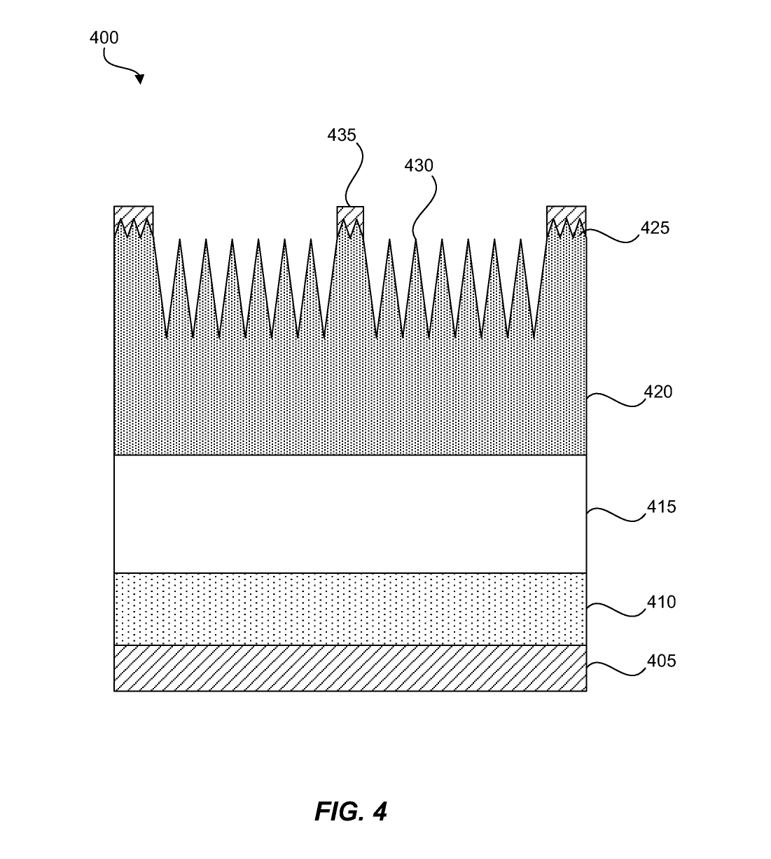

FIG. 4 illustrates cross-sectional side view of a photovoltaic solar cell device 400 in accordance an embodiment of the present technology. The photovoltaic device can include a bulk semiconductor region 415, a doped semiconductor region 410, and a backside contact 405. The device 400 can also include another doped region 420. As has been set forth herein, the dopants can be introduced via a pulsed laser process.

The photovoltaic device 400 of FIG. 4 includes first 430 and second 425 regions formed on or near the top surface of the device. The first and second regions in this example include a texture with textured features having a smaller height in the selective emitter or second regions and a larger height in active or first regions. Although this example depicts textures in both first and second regions, in one implementation textured features are formed in the first regions and surfaces in the second regions are left smooth for better contact formation over the second regions. The textured features can include, for example, pyramid, inverted pyramid and cone features. These features can redirect or diffract the incident light at an angle that allows for the light to enter and be confined within the device, causing an anti-reflecting, light trapping effect and thereby increasing the probability the light entering the device will be absorbed.

In one aspect, changing a laser parameter to change from processing a first region to processing a second region can be a gradual change or an abrupt change. For example, a gradual change in the parameter can result in a transition region between the first and second regions which can gradually transition from the first region having larger microstructures or nanostructures on the top surface to a second region having smaller or no microstructures or nanostructures formed at the surface.

The lasing process can be used to create textured features on the surface of the device that can effectively work as fiducials that can be instrumental in aligning any automated tool for further manufacturing steps. Additionally, the lasing process can remove any fiducial texturing and replace such fiducial texturing with microstructures for absorbing and diffracting incident light.

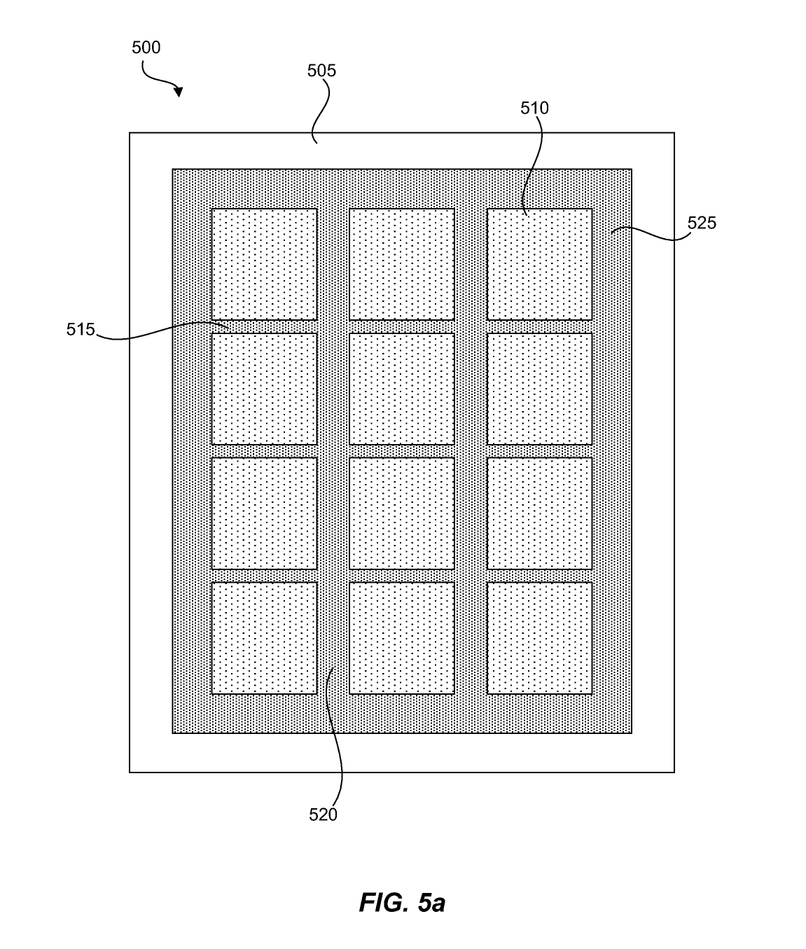

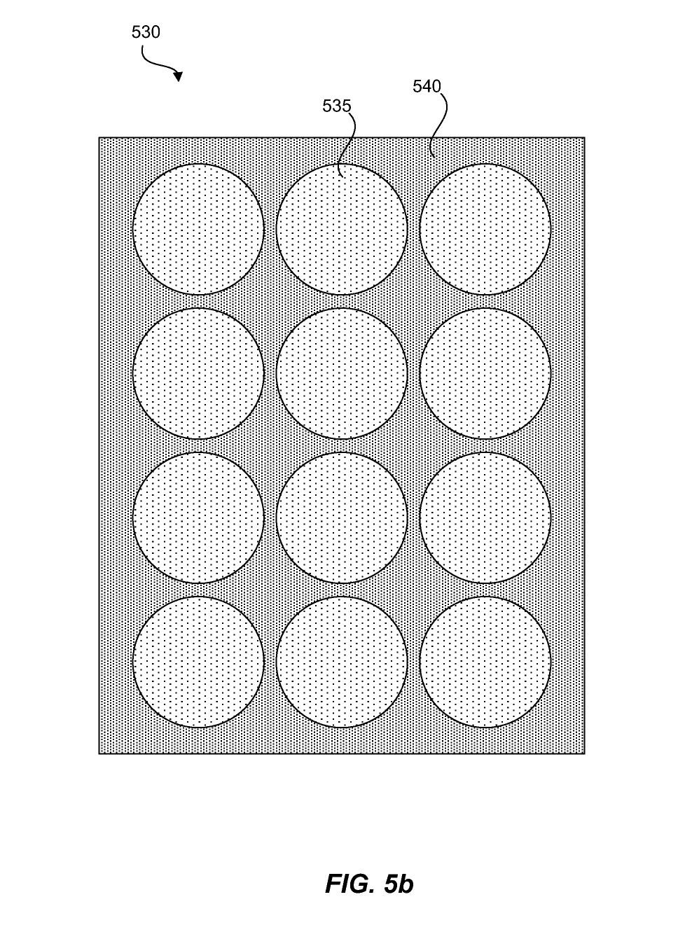

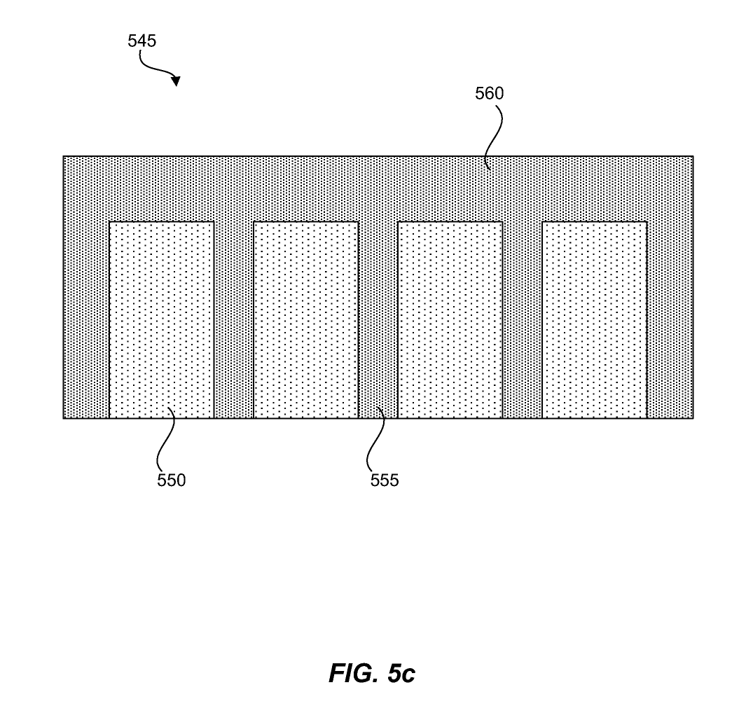

FIG. 5a illustrates an example embodiment of contact geometries on a top surface of a photovoltaic device 500 that has been processed according to the present technology. The photovoltaic device may include a silicon-based substrate 505, a first exposed textured region 510, and a second region 515, 520, and/or 525 that has been covered by a electrically conductive material. The first textured region can have light dispersing features for diffusing incident light into the device. The second region can be formed by methods described herein. One region of the contact geometry can include metal grid electrodes 515. The metal grid electrodes can have any desirable width. In a specific example, however, a width of the metal grid electrodes can be from about 10 μm to about 50 μm. Another region of the contact geometry can include a bus-bar 520. A width of the bus-bar may typically be in the range of from about 2000 μm to about 5000 μm. The bus-bars may be as much as ten times the width of the grid electrodes or more. The larger widths of the bus-bars are designed to handle current flow from multiple of the grid electrodes. Optionally, the contact geometry can include a contact border 525 that may be comprised of a metal material utilized for current transfer from the bus-bar and grid electrodes to other circuitry (not shown). While the contact geometry of FIG. 5a is illustrated as including quadrilateral-shaped regions being disposed in a grid-like pattern, other contact geometry configurations are also contemplated and are considered to be within the scope of this disclosure. For example, FIG. 5b illustrates a device 530 configuration wherein the contacts 540 are formed surrounding circularly shaped active regions 535. FIG. 5c illustrates a device 545 configuration having a row of active regions 550 separated by metal grid electrodes 555, which are interconnected by a bus-bar 560.

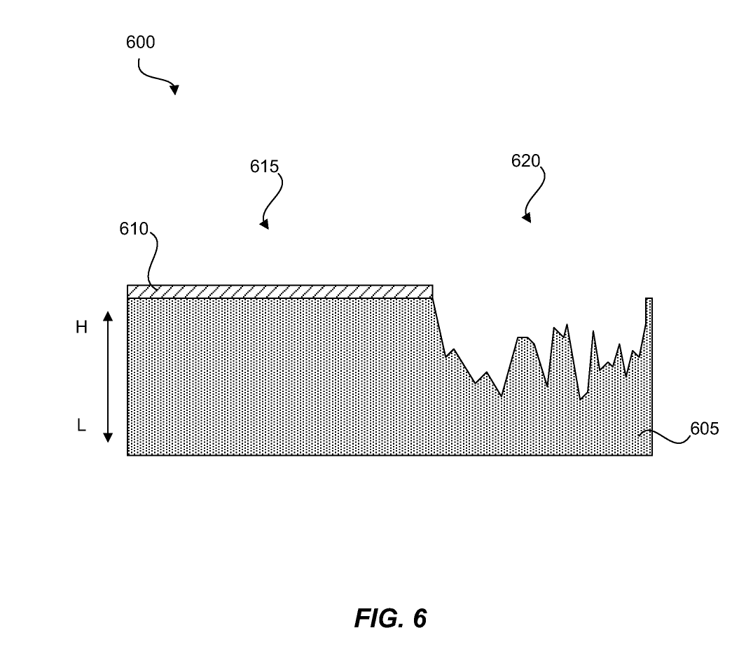

FIG. 6 illustrates a cross-sectional view of a semiconductor device 600 that has been laser processed to form a first textured region 620 and a second emitter region 615. The semiconductor substrate 605 can be a silicon-based material which can be doped with a charge donating constituent. The laser processing can dope the substrate while simultaneously altering the topology of the substrate. In other words, laser processing the substrate can create a micro-structured and/or nano-structured topography while doping the substrate at the same time. In one aspect, the laser processing to create the textured active region can result in a randomly textured region as shown in FIG. 6. In another aspect, a substantially uniformly textured active region may be created with the laser processing (not shown).

The dopant(s) can be driven into the semiconductor material during the laser processing. For example, a first dopant can be driven into the first region and a second dopant can be driven into the second region. Typically, a device may have a higher dopant concentration H nearer a top of a device and a lower dopant concentration L nearer a bottom of a device as a result of a doping process.

In one aspect, the first and second dopants may comprise a same dopant material but differ in a dopant concentration driven into the respective regions.

In one aspect, where the first and second dopant comprise different species the semiconductor substrate may be doped with the first and second dopants in successive steps in conjunction with corresponding laser processing steps.

After the dopant(s) have been driven in to the first and second regions, a dopant concentration in the second region (i.e., the emitter region) can be further increased by forcing additional dopant into the second region. For example, the additional dopant can be a same or different dopant as originally applied to the second region and can be applied through a subsequent laser driven process, through ion bombardment, etc.

A conductive layer 610, such as a metal layer, can be deposited over the second region 615 to form contacts for the photovoltaic device 600.

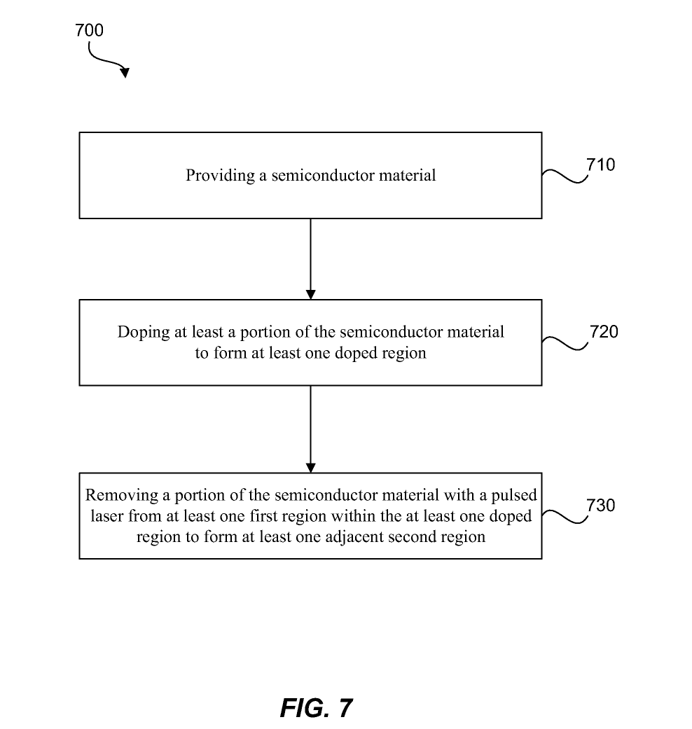

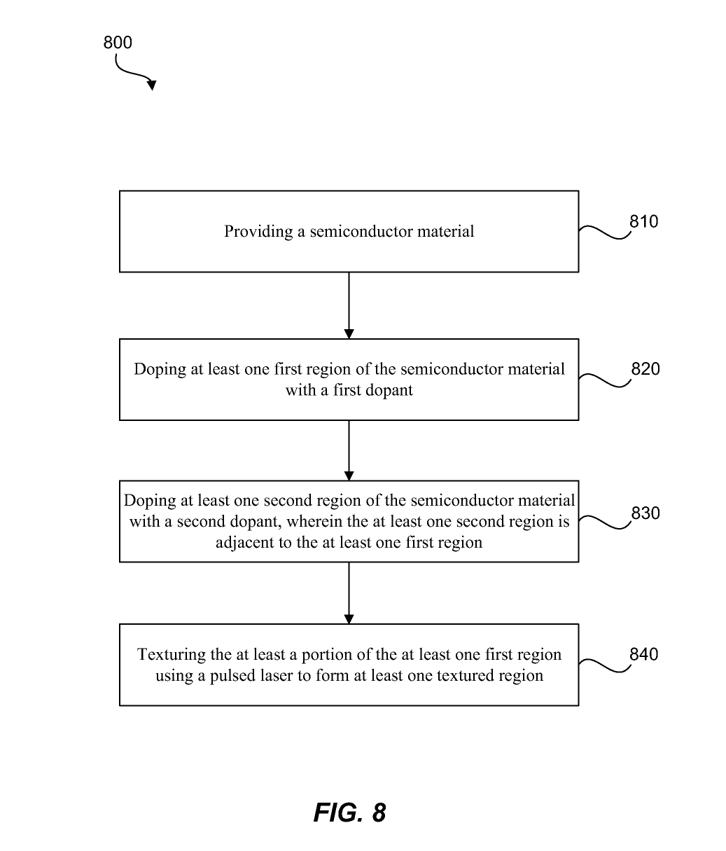

Referring to FIG. 7, a flow diagram of a method 700 for making a semiconductor device is illustrated in accordance with an example of the present technology. The method includes providing 710 a semiconductor material and doping 720 at least a portion of the semiconductor material to form at least one doped region. The method further includes removing 730 a portion of the semiconductor material with a pulsed laser from at least one first region within the at least one doped region to form at least one adjacent second region.

Some of the examples described above relate to ablating semiconductor material in the first region using energy in the laser radiation. As another option, however, a method can include doping at least a portion of the semiconductor material to form a doped region and then selectively laser processing the doped region to create substantial damage without ablation of semiconductor material. The selectively damage areas of the doped region can then be oxidized. There exist various chemistries as known to those of skill in the art that can selectively oxidize the silicon where the damage is located. After the damaged areas are oxidized, the oxidization can be etched off of the semiconductor material, which selectively removes the damage, thereby selectively removing doped damaged material. As a result, emitter regions having lower sheet resistance and higher dopant concentrations can be formed through oxidation and oxidization etching.

Referring to FIG. 8, a flow diagram of a method 800 for making a semiconductor device is illustrated in accordance with another example of the present technology. The method includes providing 810 a semiconductor material, doping 820 at least one first region of the semiconductor material with a first dopant, and doping 830 at least one second region of the semiconductor material with a second dopant. The at least one second region is adjacent to the at least one first region. The method further includes texturing 840 the at least a portion of the at least one first region using a pulsed laser to form at least one first textured region. As has been described, the first and second dopants can be different dopant species or a same dopant in different concentrations, where the different concentrations in some examples can result from texturing the portion of the at least one first region.

Other variations on the process of doping first and second regions with first and second dopants and texturing a portion of the first region are also contemplated. In one example, the laser can be used to selectively create damage in the semiconductor material before the semiconductor material is doped. The semiconductor material can be oxidized using an oxidation chemistry that selectively oxidizes the laser damaged regions more than the non-damaged regions. A dopant can then be applied to the semiconductor material. The oxidization of the semiconductor material can act as an imperfect barrier to doping. As a result, the more heavily oxidized damaged regions are doped to a lesser extent than the un-oxidized or lesser oxidized undamaged regions. The oxide from the oxidization can then be etched off of the semiconductor material. The oxide masks the laser-damaged or textured regions when doping, resulting in higher concentration of dopant in emitter regions and lower concentrations of dopant in the textured or active regions.

In another example process, the semiconductor material (or at least a portion of one side thereof) can be oxidized. A laser processing step can be performed to selectively remove at least a portion of oxide from the oxidization. Subsequently, the semiconductor material can be doped with one or more dopants and then etched to remove the oxide. Again, the oxide acts as a mask or barrier, causing emitter regions to be formed where the portion of the oxide has been removed and active regions to be formed where the oxide was not laser processed.

The following are some brief example processes which may be used to create photovoltaic devices, and which can be understood in terms of the foregoing description. In one example, a semiconductor material is first doped and then laser processed to create a textured region, to selectively damage the semiconductor material, and to remove dopant. In another example, a semiconductor material is first doped and then laser processed for texturing, selective damaging, and/or dopant removing. After the laser processing, damaged areas can be oxidized and then oxide etched to remove damage and doped material. In another example, a selective laser process is used to texture and damage a semiconductor substrate. The semiconductor substrate can then be doped and oxidized, greater oxidization occurring at the damaged regions. An oxide etch can then be used to remove dopant and damage. In another example, a selective laser process is used to texture and damage the semiconductor material. The damage is oxidized to form a dopant barrier in the damaged regions. The semiconductor substrate can be doped. An oxide etch can be used to remove dopant and damage. In yet another example, a surface of the semiconductor substrate can be oxidized to form a dopant barrier, followed by selective laser processing to texture and ablate the oxide. The semiconductor substrate can be doped and then have an oxide etch applied thereto in order to remove oxide. A laser damage DRE can be performed to remove damaged material from the semiconductor substrate.

The present technology can address various shortcomings and inefficiencies found in prior photovoltaic devices and manufacturing methods. For example, the textured surfaces can increase light capture/absorption, resulting in a more efficient solar cell device. Surfaces can be textured and selective emitters in some examples can be formed in one or two steps, resulting in greater simplicity and cost savings. The texturing and/or emitter formation can be performed in one patterned step where prior methods are typically blanket applied and involve multiple patterned steps. The present technology also provides various controls for controlling texture feature sizes.

It is to be understood that the above-described arrangements are only illustrative of the application of the principles of the present disclosure. Numerous modifications and alternative arrangements may be devised by those skilled in the art without departing from the spirit and scope of the present disclosure and the appended claims are intended to cover such modifications and arrangements. Thus, while the present disclosure has been described above with particularity and detail in connection with what is presently deemed to be the most practical embodiments of the disclosure, it will be apparent to those of ordinary skill in the art that numerous modifications, including, but not limited to, variations in size, materials, shape, form, function and manner of operation, assembly and use may be made without departing from the principles and concepts set forth herein.

What is claimed is:

1. A method for making a semiconductor device, comprising the steps of:
providing a semiconductor material;
doping at least a portion of the semiconductor material to form at least one doped region;
removing a portion of the semiconductor material with a pulsed laser from at least one first region within the at least one doped region to form at least one adjacent second region.

2. The method of claim 1, wherein the step of removing a portion of the semiconductor material with a pulsed laser includes forming textured features on a surface of the at least one first region using the pulsed laser.

3. The method of claim 2, wherein the textured features have a peak to valley height of from about 1 nm to about 5 μm.

4. The method of claim 2, wherein the textured features have a peak to valley height of from about 1 nm to about 1 μm.

5. The method of claim 1, wherein the pulsed laser removes the portion of the semiconductor material with a laser pulse having a duration from about 10 femtoseconds to about 900 picoseconds.

6. The method of claim 1, wherein a sheet resistance in the at least one doped region is from about 0.001 to about 60Ω/□.

7. The method of claim 1, wherein the at least one first region has a higher sheet resistance than the at least one second region.

8. The method of claim 7, wherein the sheet resistance of the at least one first region is approximately two times greater than the sheet resistance of the at least one second region.

9. The method of claim 7, wherein removing the portion of the doped semiconductor material increases the sheet resistance of the at least one first region.

10. The method of claim 1, further comprising the step of depositing an electrically conductive material on the at least one second region.

11. The method of claim 1, further comprising applying a damage removal etch to the semiconductor material.

12. The method of claim 11, wherein the damage removal etch is a chemical etch.

13. The method of claim 1, wherein an average removal depth to which the portion of the semiconductor material is removed with the pulsed laser is from about 1 nm to about 3 microns.

14. A method for making a semiconductor device, comprising the steps of:
providing a semiconductor material;
doping at least one first region of the semiconductor material with a first dopant;
doping at least one second region of the semiconductor material with a second dopant, wherein the at least one second region is adjacent to the at least one first region; and
texturing at least a portion of the at least one first region using a pulsed laser to form at least one textured region.

15. The method of claim 14, wherein the first dopant and the second dopant comprise a same dopant species in different dopant concentrations.

16. The method of claim 14, wherein the first dopant and the second dopant are different species.

17. The method of claim 14, wherein the step of texturing further comprises lasing the at least one first region to form textured features therein.

18. The method of claim 14, wherein the steps of doping the at least one first region and doping the at least one second region comprise a technique selected from the group consisting of ion implanting a dopant, laser doping, diffusion doping, and combinations thereof.

19. The method of claim 14, wherein the steps of doping the at least one first region and texturing the at least one first region are performed substantially simultaneously by the pulsed laser.

20. The method of claim 14, further comprising the step of decreasing a sheet resistance in the at least one second region.

21. The method of claim 20, wherein decreasing the sheet resistance in the at least one second region includes further doping of the at least one second region.

22. The method of claim 14, wherein the step of doping the at least one first region comprises the step of doping the at least one first region to a sheet resistance of from about 80 to about 200Ω/□.

23. The method of claim 14, wherein the step of doping the at least one first region comprises the step of doping the at least one first region to a sheet resistance of from about 100 to about 150Ω/□.

24. The method of claim 14, wherein the step of doping the at least one second region comprises the step of doping the at least one second region to a sheet resistance of from about 0.001 to about 60Ω/□.

25. The method of claim 14, wherein the step of doping the at least one second region comprises the step of doping the at least one second region to a sheet resistance of from about 0.001 to about 40Ω/□.

26. The method of claim 14, wherein the steps of doping the at least one first region and doping the at least one second region comprise doping the at least one first region and the at least one second region to a sheet resistance ratio of at least about 1.5:1, respectively.

27. A photovoltaic device, comprising:
a semiconductor material;
at least one doped first region on the semiconductor material, wherein the at least one doped first region includes at least a portion of one laser textured region including textured features; and
at least one doped second region on the semiconductor material adjacent to the at least one doped first region.

28. The device of claim 27, wherein the at least one doped first region and the at least one doped second region are doped with one or more dopants selected from the group consisting of aluminum (Al), carbon (C), oxygen (O), antimony (Sb), arsenic (As), phosphorous (P), germanium (Ge), sulfur (S), selenium (Se), tellurium (Te), boron (B), fluorine (F), nitrogen (N), or any other group III, IV, V, VI and/or VII atoms, and combinations thereof.

29. The device of claim 27, wherein the at least one doped second region has a lower sheet resistance than the at least one doped first region.

30. The device of claim 27, further comprising an electrically conductive layer electrically coupled to at least a portion of the at least one doped second region.

31. The device of claim 30, wherein the electrically conductive layer is directly coupled to the at least a portion of the at least one doped second region.

32. The device of claim 27, further comprising a secondary textured region on an opposite side of the semiconductor material as the laser textured region of the at least one doped first region.
